(19) United States
(12) Patent Application Publication
(10) Pub. No.: US 2021/0313966 A1
(43) Pub. Date: Oct. 7, 2021

(54) ACTIVE ELECTROMAGNETIC INTERFERENCE (EMI) FILTER FOR COMMON-MODE EMI REDUCTION

(71) Applicant: Texas Instruments Incorporated, Dallas, TX (US)

(72) Inventors: Ashish KUMAR, Santa Clara, CA (US); Yongbin CHU, Plano, TX (US); Yogesh Kumar RAMADASS, San Jose, CA (US)

(21) Appl. No.: 17/223,835

(22) Filed: Apr. 6, 2021

Related U.S. Application Data
(60) Provisional application No. 63/006,417, filed on Apr. 7, 2020.

(51) Int. Cl. H03H 11/12; H03H 7/01

(52) U.S. Cl. CPC H03H 11/12; H03H 7/0115

(57) ABSTRACT

A system includes a conductive chassis having a first ground terminal. The conductive chassis couples to a switching circuit having a second ground terminal and having a first switching frequency. The second ground terminal is electrically isolated from the first ground terminal. An active electromagnetic interference (EMI) filter has an output and first and second inputs, and is configured to receive a first AC voltage having a second switching frequency at the first input, receive a second AC voltage having the second switching frequency at the second input referenced to the first ground terminal, sense noise having the first switching frequency on at least one of the first or second inputs, and generate an injection signal at the output based on the detected noise. The output couples to at least one of the first or second inputs.

### CROSS-REFERENCE TO RELATED APPLICATION

This application claims priority to U.S. Provisional Application No. 63/006,417, filed Apr. 7, 2020, which is hereby incorporated by reference.

### BACKGROUND

Equipment that is connected to the alternating current (AC) mains generally must meet certain electromagnetic interference (EMI) requirements to avoid, or at least reduce, electrical noise generated by the equipment from being imposed on the AC mains itself. The EMI requirements may vary from location to location (e.g. from country to country). Two types of EMI noise include differential mode noise and common mode noise. In the case of differential mode noise, a noise current flows in the same path as the power supply current and thus flows in opposite directions on the power supply positive and negative terminals of the equipment. In the case of common mode noise, noise current flows in the same direction on both the power supply positive and negative terminals.

### SUMMARY

In at least one example, a system includes a conductive chassis having a first ground terminal. The conductive chassis couples to a switching circuit having a second ground terminal and having a first switching frequency. The second ground terminal is electrically isolated from the first ground terminal. An active electromagnetic interference (EMI) filter has an output and first and second inputs, and is configured to receive a first AC voltage having a second switching frequency at the first input, receive a second AC voltage having the second switching frequency at the second input referenced to the first ground terminal, sense noise having the first switching frequency on at least one of the first or second inputs, and generate an injection signal at the output based on the detected noise. The output couples to at least one of the first or second inputs.

### BRIEF DESCRIPTION OF THE DRAWINGS

FIG. 1 is a block diagram of an example of common-mode EMI noise.

FIG. 2 is a schematic illustrating the use of an amplifier to increase the effective capacitance coupled to the output of the amplifier.

FIG. 3 shows a block diagram of an embodiment of a system that includes an active EMI filter in accordance with an example.

FIG. 4 is a circuit showing an embodiment in which the active EMI filter includes a high-pass filter circuit and an amplifier, the output of which is coupled to an AC conductor in accordance with an example.

FIG. 5 is a circuit showing an embodiment in which the output of the active EMI filter's amplifier is coupled to a second AC conductor in accordance with an example.

FIG. 6 is a circuit showing an embodiment in which the output of the active EMI filter's amplifier is coupled to both the first and second AC conductors in accordance with an example.

FIG. 7 is a circuit showing an embodiment in which an active EMI filter is provided in a 3-phase, 4-conductor system.

FIG. 8 is a circuit showing additional detail for the active EMI filter of FIG. 6.

FIG. 9 is a circuit showing an example of a high-pass filter usable as part of the active EMI filter.

FIGS. 10-13 are circuits showing various options for generating an earth ground referenced supply voltage for the active EMI filter.

FIGS. 14 and 15 illustrate options for generating an earth ground referenced reference voltage for an amplifier provided within the active EMI filter.

### DETAILED DESCRIPTION

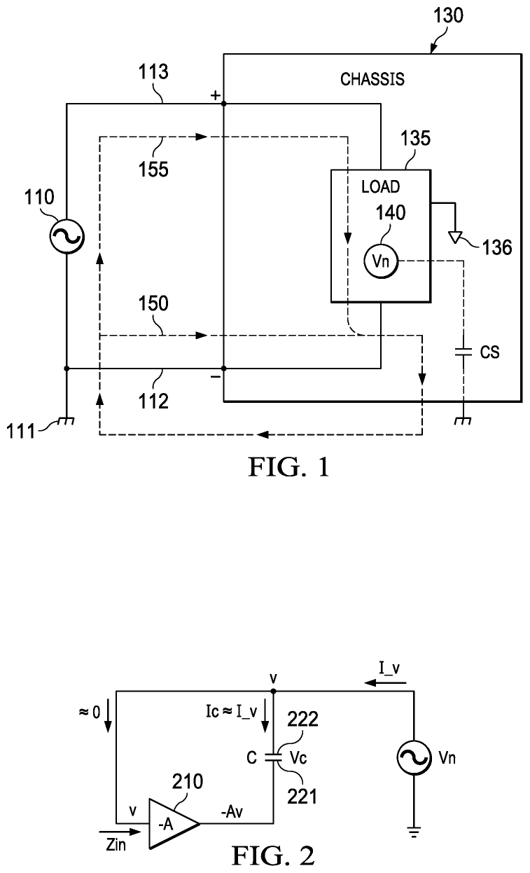

The embodiments described herein are directed to an active EMI filter that reduces common mode EMI noise. FIG. 1 is illustrative of the occurrence of common mode noise. FIG. 1 shows an AC power supply 110 coupled via a conductor 113 to a positive (POS) power terminal of an electrical load 135 and via a conductor 112 to a negative (NEG) power terminal of the load 135. Conductors 112 and 113 may be wires or other types of electrically conductive elements. The POS and NEG power terminals may be connectors or integrated into one connector socket mounted in a chassis 130. The chassis 130 is conductive (e.g., constructed of metal), The chassis 130 contains the electrical load 135 which may be any type of electrical device. In one example, the load 135 includes an alternating current-to-direct current (AC-to-DC) converter to generate a DC voltage responsive to the AC voltage from the AC power supply 110. The DC voltage generated by the AC-to-DC converter is useful to power other electrical circuits within load 135. The AC voltage (the AC power supply 110) may be the AC mains of the structure (e.g., house, factory, office building, etc.) in which the chassis 130 and its load 135 reside. In some countries, the AC voltage is 120 VAC at a frequency of 60 Hz. In other countries, the AC voltage is 230 VAC at a frequency of 50 Hz. The AC voltage from the AC power supply 110 is referenced to earth ground 111. The conductive chassis 130 also is connected to earth ground. The DC voltages produced and used within load 135 are referenced to a different ground 136 (i.e., not earth ground 111).

Noise voltage (Vn) 140 represents a voltage of noise generated within the load 135. In the example in which the load 135 includes a switching circuit, Vn 140 may be noise having a frequency at approximately the switching frequency of the switching circuit (e.g., 50 KHz, 100 KHz, 200 KHz, etc.). The frequency of the noise (e.g., 50 KHz, 100 KHz, 200 KHz, etc.) represented by Vn 140 is substantially higher than the frequency of the AC voltage (e.g., 50 Hz or 60 Hz) from the AC power supply 110.

Capacitor CS represents a stray capacitance that may form between the load 135 and the conductive chassis 130. Because the chassis 130 is connected to earth ground, when a stray capacitance forms, noise current (shown in dashed line) generated by Vn 140 can flow through the stray capacitance CS to earth ground and then from earth ground through conductor 112, through the NEG terminal, and back to Vn 140. This noise current loop is shown as common mode noise current 150. Similarly, some of the noise current (shown as common mode noise current 155) can also flow through conductor 113, through the POS terminal, and back to Vn 140.

The direction of current flow noise currents 150 and 155 is the same—the currents flow into the respective POS and NEG power terminals. Because the direction of current flow of noise currents 150 and 155 is the same, this type of noise is referred to as common mode noise. Common mode noise typically is attenuated through the use of passive EMI filters, which are low-pass filters comprising, for example, a combination of an inductor and a capacitor (an “LC” filter). The passive LC filter is a low-pass filter whose corner frequency is configured to be above the frequency of the AC voltage (e.g., 10 times higher than the frequency of the AC voltage), but below the frequency of the common mode noise. This allows a passive LC filter to transmit the AC voltage without attenuation, while substantially attenuating the common-mode noise. In one example, the AC voltage frequency is 50 to 60 Hz and the common mode noise frequency is 50 KHz or higher, and the corner frequency of the passive LC filter is at approximately 500 Hz or higher but less than 50 KHz. The corner frequency of an LC filter is proportional to

$$\frac{1}{\sqrt{L * C}} ,$$

where L is the inductance of the inductor and C is the capacitance of the capacitor. Accordingly, the corner frequency of an LC filter is inversely related to the product of L and C. An example of a passive LC filter is shown in FIGS. 2-8 and described below.

The capacitor of an LC filter may be coupled to earth ground. To avoid dangerous leakage currents from shocking a person that touches the conductive chassis of electrical equipment in which the chassis is, such as by mistake or malfunction, not connected to earth ground, the impedance of the capacitor should be above a predetermined minimum level to reduce the leakage current through the person from the chassis to earth ground. The impedance of a capacitor is inversely related to the product of its capacitance and frequency of the current flowing through the capacitor (capacitor impedance is proportional to

$$\frac{1}{2 * π * f * C} ,$$

where r is frequency given in units of Hertz, Hz). Accordingly, the capacitance of the capacitor should be small enough (e.g., less than a predetermined maximum capacitance) at line frequency (e.g., 50 or 60 Hz) so that its impedance is large enough to avoid potentially harmful leakage currents from occurring. Accordingly, any leakage current that may form and flow through a person should be small enough so as not be considered harmful to the person.

However, limiting the capacitance of the LC filter to a small value to address the leakage current problem means that the inductance L of the inductor must be large to ensure a sufficiently low corner frequency (per above, the corner frequency is proportional to

$$\frac{1}{\sqrt{L * C}} )$$

so mat common mode noise is substantially attenuated. As a result, the physical size of the inductor may need to be undesirably large which also may result in an expensive inductor. Multiple such inductors may exist in the passive EMI filters and each may need to be large and expensive for this reason.

The embodiments described herein include an active EMI filter that senses higher frequency (e.g., 50 KHz, 100 KHz, 200 KHz, etc.) noise on the AC conductors (e.g., conductors 113 and 112 in FIG. 1), and generates an “anti-noise” signal which it injects into at least one of the AC conductors to reduce the magnitude of the higher frequency common mode noise. Anti-noise is a signal that is generally equal to the common mode noise signal, but 180 degrees out of phase with respect to the common mode noise signal. The active EMI filter includes first and second high-pass filters coupled to respective AC conductors. Each high-pass filter attenuates the lower frequency (e.g., 50 Hz, 60 Hz) signals of its respective AC conductor thereby permitting the higher frequency content (noise) to be output by the high-pass filter. The outputs of the high-pass filters are coupled together thereby combining (e.g., adding) the high frequency signals from the AC conductors. The combined high frequency content is a signal that is approximately equal (same frequency and in-phase) to the common mode noise on the AC conductors.

The active EMI filter also includes an amplifier that amplifies the combined signal from the high-pass filters and inverts the amplified signal to produce the anti-noise signal which is injected back into at least one of the AC conductors to reduce the common mode EMI noise. In one example, the amplifier is an inverting amplifier which both amplifies and inverts the input common mode noise signal from the high-pass filters.

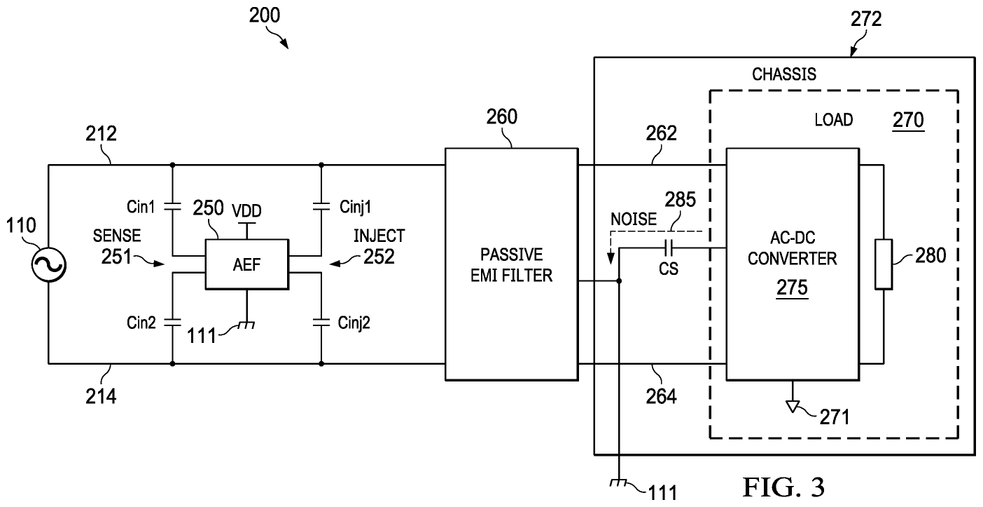

The system also may include passive EMI filters in combination with the active EMI filter. Because of the use of an active EMI filter, the inductors of the passive EMI filter can be smaller than otherwise would be the case in absence of the active EMI filter. The reduction in inductor size can be understood by considering the active EMI filter circuit as a “capacitance” amplifier. FIG. 2 shows the concept of capacitance amplification. The amplifier mentioned above, and described in greater detail herein (e.g., FIG. 3) is shown in FIG. 2 as amplifier 210. A noise voltage, Vn, is sensed by amplifier 210, multiplied by a negative gain, −A, and the amplified signal, −A*Vn from amplifier 210 is applied to the bottom terminal 221 of a capacitor C, whose upper terminal 222 is connected to the noise voltage Vn. The noise current is I_v. The impedance, Zin, to the amplifier 210 is relatively high and thus the amplifier's input does not sink any, or much, current. Accordingly, most or all of the noise current I_v from the noise voltage source flows to the capacitor C and is shown in FIG. 2 as Ic (which is approximately equal to I_v).

The voltage across capacitor C is Vc which is the difference between the voltages on terminals 221 and 222. The capacitor voltage Vc is thus (Vn−(−A*Vn)) which is (1+A)Vn. The current versus voltage relationship for a capacitor C is

$$i = C \frac{d v}{d t} .$$

Accordingly, the current is equal to the rate of change of the voltage with respect time multiplied by the capacitance. The voltage across capacitor C is (1+A)Vn. The current Ic through capacitor C is:

$$Ic = C \frac{d ( ( 1 + A ) V n )}{d t} \qquad ( 1 )$$

Because Ic is approximately equal I_v, then:

$$I\_v = C \frac{d ( ( 1 + A ) V n )}{d t} \qquad ( 2 )$$

which also is expressed as:

$$I\_v = ( 1 + A ) C \frac{d ( V n )}{d t} \qquad ( 3 )$$

Per Eq. (3) above, it can be observed that, at the higher frequencies of the common mode noise (e.g., 50 KHz), the current is equal to the rate of change of Vn multiplied by (1+A)C. Accordingly, (1+A)C is the “effective” capacitance between the output of the amplifier 210 and the conductor having the noise voltage Vn. The effective capacitance is the actual capacitance of capacitor C multiplied by a factor (1+A) that is function of the absolute value of the gain of the amplifier.

When used in a passive LC filter with a predetermined corner frequency, the larger effective capacitance (1+A)C (at the frequency of interest to be attenuated) allows the inductance L to be smaller. The active EMI filter described herein provides this capacitance amplification effect at higher frequencies (e.g., 50 KHz and higher), while not providing amplification at line frequencies (50 Hz or 60 Hz) because such lower frequencies are attenuated through the use of the high-pass filter. Accordingly, the active EMI filter attenuates high-frequency common mode noise while maintaining the same line-frequency leakage current as an “unamplified” capacitor.

FIG. 3 shows an embodiment of a system 200 that includes an active EMI filter (AEF) 250, a passive EMI filter 260, and a load 270. The AC power supply 110 is a single-phase AC voltage source. Conductor 212 (e.g., a wire) includes a line voltage and conductor 214 includes a neutral voltage. The line and neutral voltages are referenced with respect to earth ground 111. In one example, the line voltage on conductor 212 is 180 degrees phase shifted with respect to the neutral voltage on conductor 214, but in another example, the conductor 214 is connected to earth ground 111.

The AEF 250 has a sense input 251 and an injection output 252. The sense input 251 is coupled to the line conductor 212 via capacitor Cin1 and to the neutral conductor 214 via capacitor Cin2 and senses/detects the common mode noise on the line and neutral conductors 212 and 214. The injection output 252 is coupled to the line conductor 212 via capacitor Cinj1 and to the neutral conductor via capacitor Cinj2. In other examples as described below, the injection output is coupled through a capacitor to only one of the conductors, not both. The capacitors Cinj1 and Cinj2 may be referred to as “injection” capacitors because their function is to inject an anti-noise signal produced by the AEF 250 back into the line and neutral conductors 212 and 214.

The passive EMI filter 260 is coupled to the conductors 212 and 214 and includes a filtered output on output conductors 262 and 264 to the load 270. In this example, the load 270 includes an AC-DC converter 275 which converts the filtered output AC voltage from conductors 262 and 264 to a DC voltage to power a device 280. Device 280 may comprise an electrical circuit, a microprocessor, a motor, or any other type of electrical device. The load 270 resides within or on a chassis 272. The chassis 272 is conductive and is grounded to earth ground 111. The voltages generated within the load 270 are referenced to a ground 271, which is different than earth ground 111. Capacitor CS is the stray capacitance described above that may form between a noise voltage source within the load 270 and the chassis 272. Common mode noise current 285 may flow as described above.

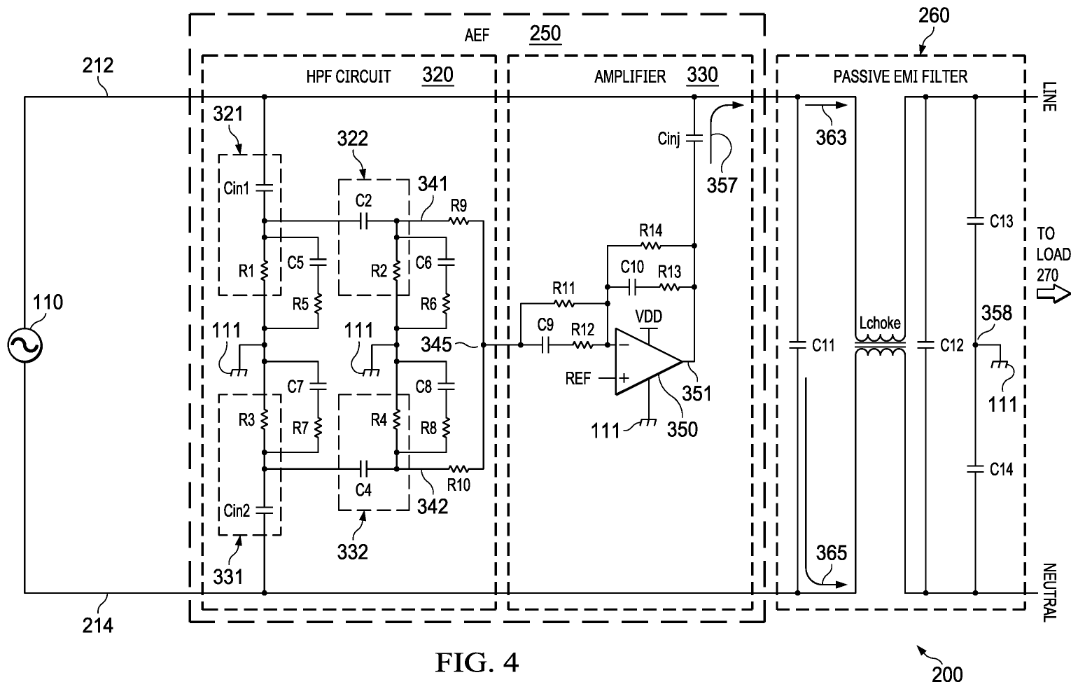

The frequency of the AC voltage on conductors 212 and 214 is the line frequency which may be, for example, 50 Hz or 60 Hz. The frequencies of the noise current 285 may be substantially higher due to the switching frequencies implemented for the load (e.g., the switching frequencies of the AC-DC converter). In one example, the frequencies of the noise current 285 are tens of KHz or higher (e.g., 50 KHz to 1 MHz). As shown and described below regarding FIG. 4, the AEF 250 includes high-pass filters that attenuate the line frequencies and pass through the frequencies of the noise current 285. The outputs of the high-pass filters are combined together (e.g., added) and the combined filter output is provided to an input of an amplifier. The addition of the filters' outputs extracts the common-mode component of the noise voltage. The amplifier generates the anti-noise signal. The output from the amplifier is coupled to the conductors 212 and 214 via respective injection capacitors Cinj1 and Cinj2 to inject the anti-noise into the conductors thereby reducing the magnitude of (attenuating) the common mode noise.

FIG. 4 shows example implementations of the AEF 250 and passive EMI filter 260. The AEF 250 in this example includes a high-pass filter circuit 320 coupled to an amplifier 330. The high-pass filter circuit 320 has a frequency response that attenuates line frequencies while passing frequencies in the range of the common mode noise produced by, for example, the load 270. In one example, the line frequencies are approximately 50-60 Hz and the common mode noise frequencies are tens of kilohertz or higher, and the corner frequency of the high-pass filter circuit 320 is above 60 Hz but below common mode noise frequency.

The magnitude of the common mode noise on conductors 212 and 214 is generally substantially smaller than the magnitude of the AC voltage produced by the AC power supply 110. To ensure adequate attenuation of the larger amplitude AC voltage from power supply 110 in the face of a smaller amplitude noise signal, in one embodiment, the high-pass filter circuit 320 is a two-stage high-pass filter. However, in other embodiments, the high-pass filter circuit 320 is a single-stage high-pass filter. Further, the filter can include more than two stages as desired. Regardless of the number of stages, the high-pass filter circuit 320 includes a high-pass filter coupled to conductor 212, which is configured to filter the voltage on conductor 212, and a high-pass filter coupled as well to conductor 214 to filter the voltage on conductor 214.

FIG. 4 illustrates that high-pass filter circuit 320 includes a two-stage high-pass filter coupled to conductor 212 comprising high-pass filters 321 and 322. The high-pass filter circuit 320 also includes a two-stage high-pass filter coupled to conductor 214 comprising high-pass filters 331 and 332. Each high-pass filter in this example includes a resistor and a capacitor (an “RC” filter). High-pass filter 321 includes capacitor Cin1 coupled to resistor R1. High-pass filter 322 includes capacitor C2 coupled to resistor R2. High-pass filter 331 includes capacitor Cin2 coupled to resistor R3. High-pass filter 332 includes capacitor C4 coupled to resistor R4.

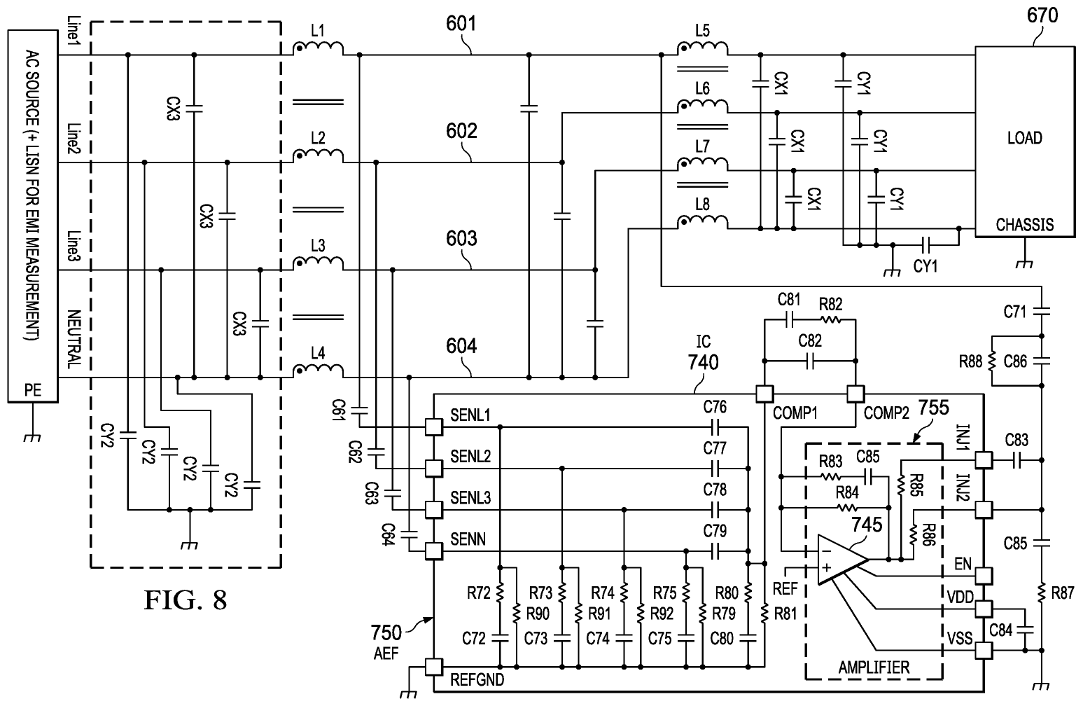

The illustrative high-pass filter circuit 320 also includes capacitors C5-C8 and resistors R5-R8. Capacitor C5 and resistor R5 are coupled in series, and the series combination of capacitor C5 and resistor R5 is coupled in parallel with resistor R1. Similarly, capacitor C6 and resistor R6 are coupled in series, and the series combination of capacitor C6 and resistor R6 is coupled in parallel with resistor R2. Further, capacitor C7 and resistor R7 are coupled in series, and the series combination of capacitor C7 and resistor R7 is coupled in parallel with resistor R3. Capacitor C8 and resistor R8 are coupled in series, and the series combination of capacitor C8 and resistor R8 is coupled in parallel with resistor R4. Capacitors C5-C8 and resistors R5-R8 may be provided to add poles and zeros to the loop gain of the system in a manner that keeps the system stable (e.g., maintaining positive phase margin). Stability of the AEF 250 is influenced by the passive EMI filter and other system components interfacing with the AEF. Depending on these components, capacitors C5-C8 and resistors R5-R8 may be optional. On the other hand, in some systems, stability considerations may require additional resistors and capacitors connected between the output of the amplifier and the injection capacitor Cinj, an example of which is shown in FIG. 8.

The filtered output of the two-stage, high-pass filter comprising filters 321 and 322 is provided on conductor 341. Similarly, the filtered output of the two-stage high-pass filter comprising filters 331 and 332 is provided on conductor 342. The filtered output signals on conductors 341 and 342 generally include only the higher frequency noise on the respective conductors because the filters have attenuated the lower frequencies of the AC voltages produced by the AC power supply 110. The output of the high-pass filter comprising filters 321 and 322 is combined with the output of the high-pass filter comprising filters 331 and 332 at a summing terminal 345. The combination of the outputs of the high-pass filters is created in FIG. 4 by coupling example conductors 341 and 342 at summing terminal 345. In the example of FIG. 4, resistor R9 couples the output of high-pass filter 322 to the summing terminal 345, and resistor R10 couples the output of high-pass filter 332 to the summing terminal 345. Resistors R9 and R10 provide additional attenuation of the filters' output signals. However, in other embodiments, resistors R9 and R10 are not present and conductors 341 and 342 are connected directly together at the summing terminal 345.

The summing terminal 345 generally includes only the combined (e.g., added) common mode noise from conductors 212 and 214, which by definition represents the common-mode component of the noise on conductors 212 and 214. The summing terminal 345 is an input to amplifier 330. Amplifier 330 in the example of FIG. 4 is configured as an inverting amplifier including an operational amplifier (op amp) 350, resistors R11-R14, and capacitors C9 and C10. The op amp 350 includes a negative (−) input and a positive (+) input and an output 351. The summing terminal 345 is coupled to the inverting input through the series combination of capacitor C9 and resistor R12. The series combination of resistor R13 and capacitor C10 is coupled between the output 351 of the op amp 350 and the negative input and implements negative feedback for the amplifier. Resistor R11 is coupled in parallel with the series combination of capacitor C9 and resistor R12, and resistor R14 is coupled in parallel with the series combination of capacitor C10 and resistor R13. The gain of the amplifier is equal to the negative of the ratio of the resistance of resistor R13 to the resistance of resistor R12 (gain is −R13/R12). Resistors R11 and R14 and capacitors C9 and C10 are provided for stability purposes. A reference voltage (REF) is coupled to the positive input of op amp 350. The supply voltage to the op amp 350 is a DC voltage, VDD, which is referenced to earth ground 111. Because the op amp 350 processes the common-mode component of the signals on conductors 212 and 214, it is convenient from an implementation viewpoint for the op amp's supply voltage (VDD) to be referenced to the common ground of the signals on conductors 212 and 214 (e.g., the earth ground 111).

Because the amplifier 330 is configured as an inverting amplifier, the output signal on the output 351 of the op amp 350 (which also is the output of the amplifier 330) has an opposite polarity (180-degree phase shift) with respect to the input signal on the summing terminal 345. In the example of FIG. 4, injection capacitor Cinj is shown coupling the output 351 of the amplifier 330 to conductor 212. The amplified and inverted common mode noise signal is injected through injection capacitor Cinj onto conductor 212 to thereby reduce or cancel out the common mode noise that may otherwise exist on conductors 212 and 214.

The passive EMI filter 260 in FIG. 4 includes capacitors C11-C14. The passive EMI filter also includes one or more inductors which function as a choke, and thus is labeled Lchoke in FIG. 4. The inductor Lchoke functions to block frequencies substantially above the line frequency of the AC power supply 110. Capacitors C13 and C14 are coupled in series between Line and Neutral with their connecting point 358 (between the capacitors) connected to earth ground 111 as shown. The combination of the effective capacitance of capacitor Cinj (the effective capacitance is the capacitance of capacitor Cinj amplified by a value of (1+A), where −A is the gain of amplifier 330), inductor Lchoke, and capacitors C13 and C14 forms an LC low pass filter.

Capacitors Cin1, Cin2, Cinj, C13, and C14 are “Y-rated” capacitors (also called Class-Y capacitors). The failure mode for a Y-rated capacitor is that it will fail open. Accordingly, if the capacitor is subject to, for example, an overvoltage condition, the capacitor will fail as an open circuit. Because capacitors Cin1, Cin2, Cinj, C13, and C14 provide conduction paths between Line/Neutral and earth ground, the potential for an overvoltage condition damaging the system is addressed by selecting Y-rated capacitors for capacitors Cin1, Cin2, Cinj, C13, and C14.

A chassis containing the circuitry of system 200 also is connected to earth ground for safety reasons. As described above, however, it is possible for the chassis' connection to earth ground to become disconnected or inadvertently omitted. Because of this possibility, if a person (who is standing on the ground and thus coupled to earth ground) were to touch the chassis, the potential would exist for a leakage current to flow from Line or Neutral through the person to earth ground thereby shocking the person. To reduce the size of any potential leakage current, the impedance of the capacitors at line frequency should be sufficiently large.

As described above, without the AEF 250 and because capacitor impedance is inversely proportional to capacitance of the capacitor, the capacitors C13 and C14 should have relatively small capacitance values. But with small capacitors, however, means that the size of the inductor Lchoke will need to be large to have the correct corner frequency. The sum of the capacitances of capacitors Cin1, Cin2, Cinj, C13, and C14 should be relatively small to reduce the potential for harmful leakage current.

As described above, the AEF 250 amplifies the effective capacitance value for capacitor Cinj (i.e., the capacitance between the output of the amplifier and the conductor to which capacitor Cinj is connected) and thus reduces its effective impedance at the higher frequencies of the common mode noise. For example, assuming a capacitance value of capacitor Cinj of 4.7 nF, in the range of 150 KHz to 1 MHz, the effective capacitance of capacitor Cinj may be 470 nF, whereas at line frequency (50-60 Hz), capacitor Cinj appears as its true capacitance, 4.7 nF (which is advantageous for leakage current concerns). The amplification of Cinj is accomplished through the amplifier 330 as described above regarding FIG. 2. Assuming that the amplifier 330 provides a closed loop gain of −A, the effective capacitance of capacitor Cinj is (1+A)*Cinj in the frequency range of the common mode noise. With the effective capacitance in the higher frequency range being substantially larger than the actual capacitance of capacitor Cinj, inductor Lchoke can be implemented to have a much smaller inductance than would otherwise be the case absent the AEF 250 in terms of having the desired corner frequency for the LC filter of the pass EMI filter 260.

In FIG. 4, the anti-noise signal is a current 357 that is added to the current flowing through conductor 212. At the frequencies of the common mode noise, the impedance of capacitor C11 is very small, and thus a portion of current 357 flows through conductor 212 as current 363 and another portion of current 357 flows through capacitor C11 as current 365 into conductor 214. Accordingly, the anti-noise signal (current 357) is added to both conductors 212 and 214 and reduces or eliminates the common mode noise in both conductors despite the output of the amplifier 330 only being connected to conductor 212.

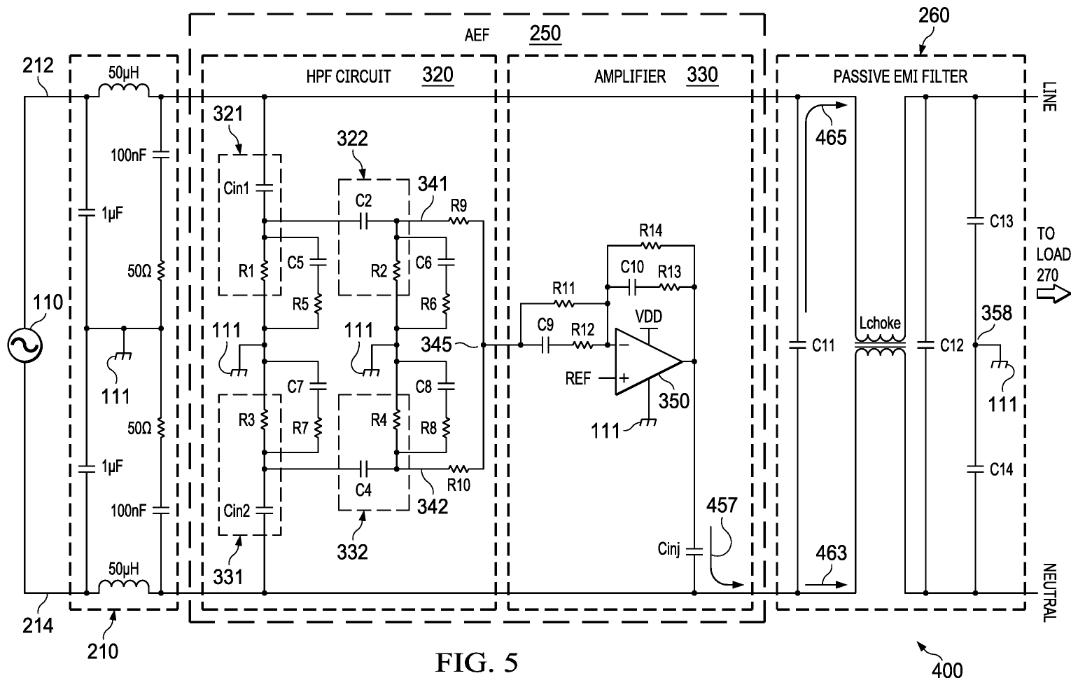

FIG. 5 shows a system 400 identical to system 200 with one difference. The difference is that in FIG. 5, the capacitor Cinj is coupled between the output of amplifier 330 and conductor 214, not conductor 212. As described above, at the frequencies of the common mode noise, the impedance of capacitor C11 is very small, and thus a portion of current 457 (anti-noise signal generated by amplifier 330) flows through conductor 214 as current 463 and another portion of current 457 flows through capacitor C11 as current 465 into conductor 212.

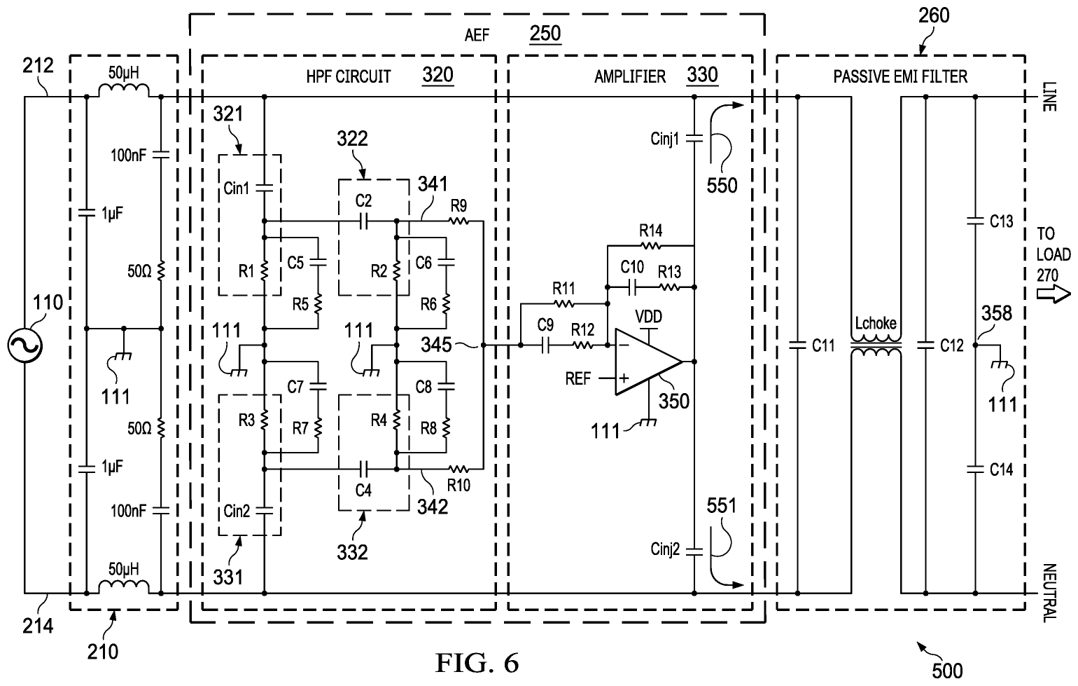

FIG. 6 shows a system 500 identical to systems 200 and 400 with one difference. In systems 200 and 400, a capacitor Cinj couples the output of the amplifier 330 to one conductor (212, 214) or the other. But in FIG. 6, the output of the amplifier 330 is coupled to both conductors 212, 214 by way of separate capacitors shown in FIG. 6 as capacitor Cinj1 and Cinj2. Capacitor Cinj1 couples the amplifier's output to conductor 212, and capacitor Cinj2 couples the amplifier's output to conductor 214. Accordingly, current 550 and current 551 are provided to both conductors 212, 214 by the amplifier 330 rather than relying on capacitor C11.

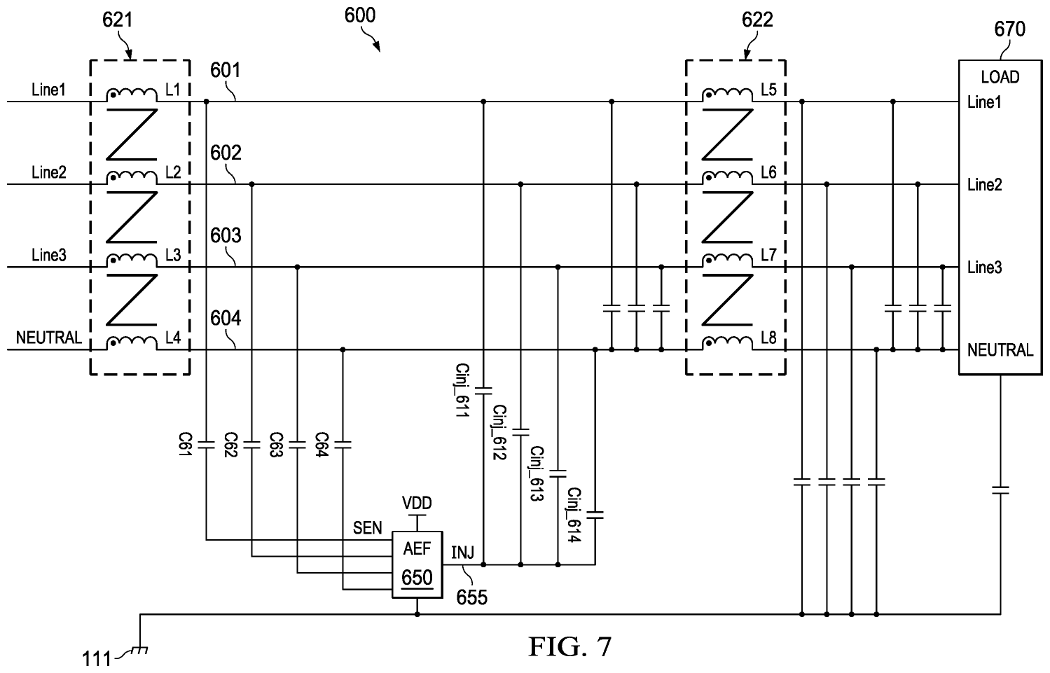

FIG. 7 shows an example of a 3-phase, 4-conductor system 600 that includes an AEF 650 coupled between a first choke 621 including inductors L1-L4 and a second choke 622 including inductors L5-L8 to provide an AC supply voltage to a load 670. In other embodiments of a 3-phase system, only one set of chokes is present, and the AEF 650 can still be used in such embodiments. In FIG. 7, the phases include Line1, Line2, Line3, and Neutral, each coupled to the AEF 650 by way of a respective capacitor. Line1 couples to the AEF 650 through capacitor C61. Line2 couples to the AEF 650 through capacitor C62. Line3 couples to the AEF 650 through capacitor C63. Neutral couples to the AEF 650 through capacitor C64. Capacitors C61-C64 are functionally equivalent to capacitors C11 and C2 in FIG. 3. The AEF 650 senses common mode noise from all four conductors 601, 602, 603, and 604, and combines the noise together to generate an anti-noise signal 655 that is injected in this example back into all four wires via injection capacitors Cinj_611, Cinj_612, Cinj_613, and Cinj_614.

In FIG. 7, the anti-noise signal produced by the AEF 650 to reduce the common mode noise is injected into all four conductors 601-604. In other embodiments, the anti-noise signal is injected into only one of the conductors (601, 602, 603, or 604), any two of the four conductors, or any three of the four conductors. Further, FIG. 7 shows an example of a 3-phase, 4-conductor system. The AEF 650 can also be used with a 3-phase, 3-conductor system (no separate neutral conductor). In a 3-phase system, the sense side of the AEF 650 includes three capacitors that respectively couple the three power conductors to the AEF 650.

FIG. 8 shows another example of a 3-phase, 4-conductor system in which an AEF 750 is coupled through one injection capacitor C71 to only one of the conductors, conductor 601 (although C71 can be coupled to any of the conductors). The AEF 750 is fabricated in the form of an integrated circuit 740 in which resistors R72-R81, R83-R86, and R90-R91, capacitors C72-C80 and C85, and op-amp 745 are fabricated on a semiconductor die. Resistor R82 and capacitors C81 and C82 are shown in the example as being external to IC 740, but in other examples, resistor R82 and capacitors C81 and C82 are fabricated as part of the IC 740 as well. Resistor R82 and capacitors C81 and C82 are provided to compensate the AEF 750 for stability purposes. A separate high-pass filter is provided for each conductor, Line1, Line2, Line3 and Neutral. Capacitor C61 is coupled to resistor R90 to form a first stage of a two-stage high-pass filter for Line1. The second stage includes capacitor C76 which is coupled to resistor R81. Similarly, capacitor C62 is coupled to resistor R91 to form a first stage of a two-stage high-pass filter for Line2, the second stage for which includes capacitor C77 coupled to resistor R81. Capacitor C63 is coupled to resistor R92 to form a first stage of a two-stage high-pass filter for Line3, the second stage for which includes capacitor C78 coupled to resistor R81. Capacitor C64 is coupled to resistor R79 to form a first stage of a two-stage high-pass filter for Neutral, the second stage for which includes capacitor C79 coupled to resistor R81. Resistor R81 is shared between the second stages of all the high-pass filters. As described above, additional components may be provided for stability reasons. In the example of FIG. 8, such stabilization components include resistor R72 connected in series to capacitor C72, the series combination of which is coupled in parallel with resistor R90. Resistor R73 is connected in series to capacitor C73, the series combination of which is coupled in parallel with resistor R91. Resistor R74 is connected in series to capacitor C74, the series combination of which is coupled in parallel with resistor R91. Resistor R75 is connected in series to capacitor C75, the series combination of which is coupled in parallel with resistor R79. Resistors R85-R88 and capacitors C83-C86 are connected between the output op amp 745 and the injection capacitor C71, and such components are also provided for stability reasons.

The op-amp 745 is configured with negative feedback as described above to form an amplifier 755. The operation of AEF 750 is largely as described above regarding AEF 250. The implementation of AEF 750 in FIG. 8 can be used as the implementation for AEF 650 in FIG. 7.

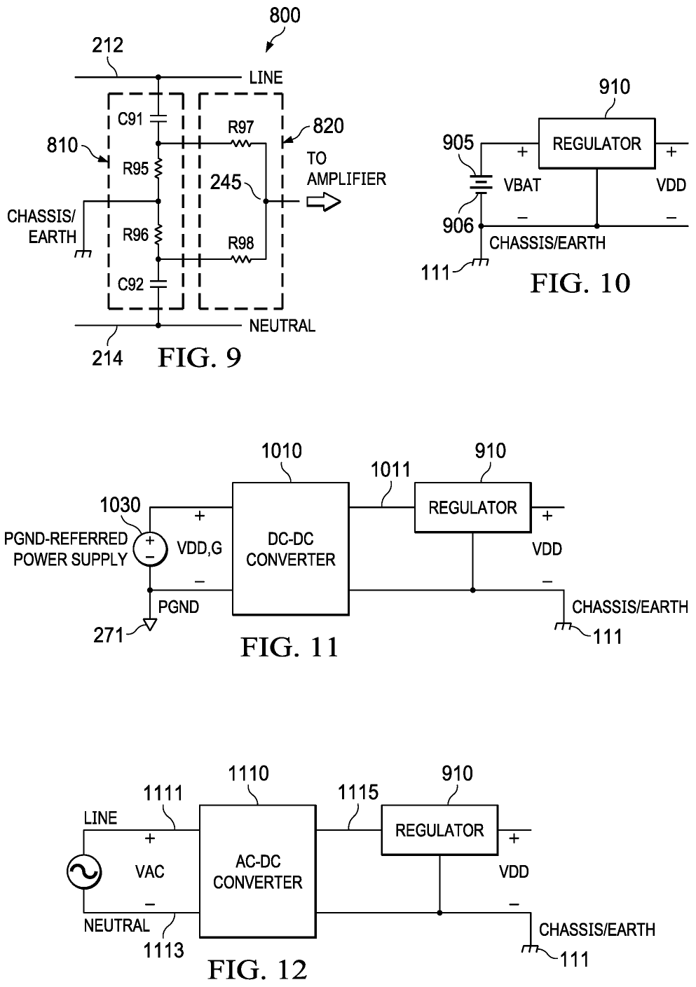

FIG. 9 shows another example of a high-pass filter 800 usable as part of the active EMI filter described herein. The high-pass filter in this example can be used as the high-pass filter for any of the embodiments described herein. The high-pass filter 800 in FIG. 9 includes a single-stage high-pass filter 810 with a resistive combiner 820. The single-stage high-pass filter includes an RC filter comprising resistor R91 and capacitor C91 for the line conductor 212, and an RC filter comprising resistor R92 and capacitor C92 for the line conductor 214. The resistive combiner 820 includes resistors R93 and R94 coupling the output of the individual RC filters to the summing terminal 345. In some embodiments, resistors R93 and R94 can be replaced by short circuits, so that the resistive combiner 820 may connect the outputs of the filters together at summing terminal 345 without the resistances of a resistive combiner.

As described above, the amplifier provided within the AEF (e.g., amplifiers 330 and 755) includes a supply voltage VDD that is referenced to earth ground. FIGS. 10-13 show examples of the generation of an earth ground-referenced supply voltage. In FIG. 10, a voltage regulator 910 is coupled to, and receives a DC voltage (VBAT) from, a battery 905. The negative terminal 906 of the battery 905 is coupled to earth ground 111. The voltage from the battery 905, VBAT is thus a DC voltage referenced to earth ground that is provided as input voltage to the voltage regulator 910, the output of which is VDD and also is referenced to earth ground 111. The voltage regulator 910 may convert the magnitude of VBAT to a different DC voltage. In one example, the voltage regulator 910 is a low drop-out regulator.

FIG. 11 illustrates a DC-to-DC converter 1010 coupled to the voltage regulator 910. The DC-to-DC converter 1010 is coupled to a power supply 1030 that produces a DC supply voltage referenced to ground 271, which is not earth ground 111. The output 1011 of the DC-to-DC converter 1010 provides a DC voltage referenced to earth ground 111. The voltage regulator 910, which receives the earth ground-referenced output voltage from DC-to-DC converter 1010, generates VDD which also is referenced to earth ground.

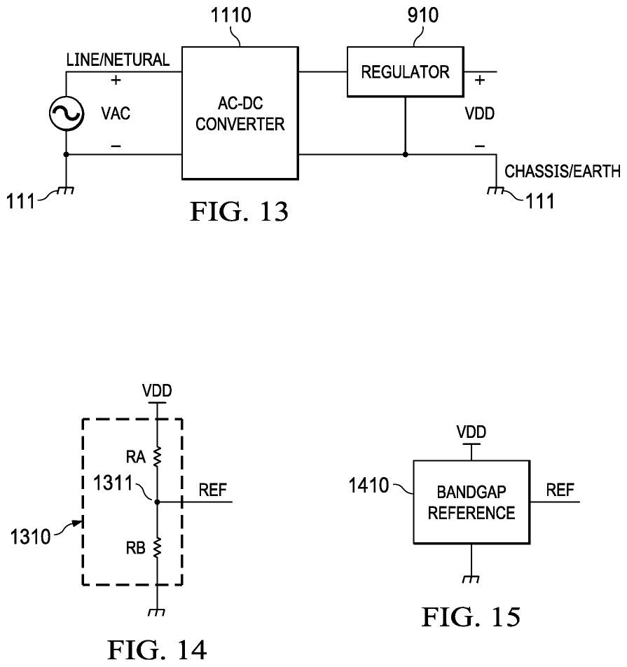

FIG. 12 illustrates an AC-to-DC converter 1110 coupled to the voltage regulator 910. AC-to-DC converter 1110 is separate from the AC-to-DC converter 275 in FIG. 2 and provides an auxiliary converter to generate VDD. The AC-to-DC converter 1110 receives an AC supply voltage comprising Line 1111 and Neutral 1113. The output 1115 of the AC-to-DC converter 1110 provides a DC voltage referenced to earth ground 111. The voltage regulator 910, which receives the earth ground-referenced output voltage from DC-to-DC converter 1010, generates VDD which also is referenced to earth ground. FIG. 13 is similar to FIG. 2 except that the input voltage to the AC-to-DC converter 1110 is an AC voltage that is referenced to earth ground 111.

As described above, the amplifier 330 receives a reference signal (REF) on its non-inverting input. The reference signal REF is a voltage that is referenced to earth ground. FIGS. 14 and 15 show two examples of the generation of an earth ground-referenced reference signal REF. FIG. 14 shows a resistor divider 1310 including resistor RA coupled in series with resistor RB between VDD and earth ground 111. VDD is generated according to any of the examples of FIGS. 10-13. The connection point 1311 between resistors RA and RB provides the reference signal REF. The magnitude of REF is VDD*RA/(RA+RB).

FIG. 15 shows an example in which the reference signal REF is the output voltage from a bandgap reference circuit 1410 implemented in accordance with any suitable such circuit. The supply voltage to the bandgap reference circuit 1410 is VDD referenced to earth ground 111. VDD is generated according to any of the examples of FIGS. 10-13.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Modifications are possible in the described embodiments, and other embodiments are possible, within the scope of the claims.

What is claimed is:

1. A circuit for reducing common mode electromagnetic interference (EMI), the circuit comprising:
a first high-pass filter having a first alternating current (AC) input and a first output;
a second high-pass filter having a second AC input and a second output, the second output coupled to the first output;
an amplifier having an amplifier input and an amplifier output, the amplifier input coupled to the first and second outputs; and
a capacitor coupled between the amplifier output and at least one of the first or second AC inputs.

2. The circuit of claim 1, wherein the first high-pass filter is a first two-stage high-pass filter, and the second high-pass filter is a second two-stage high-pass filter.

3. The circuit of claim 1, wherein the amplifier is an inverting amplifier.

4. The circuit of claim 1, wherein the capacitor is a first capacitor coupled between the amplifier output and the first AC input, and the circuit further comprises a second capacitor coupled between the amplifier output and the second AC input.

5. The circuit of claim 1, wherein the capacitor is coupled between the amplifier output and only one of the first or second AC inputs.

6. The circuit of claim 1, further comprising a third high-pass filter having a third AC input and a third output, in which:
the third output is coupled to the first and second outputs;
the first high-pass filter is configured to receive a first alternating current (AC) voltage at the first AC input;
the second high-pass filter is configured to receive a second AC voltage at the second AC input;
the third high-pass filter is configured to receive a third AC voltage at the third AC input; and
the third AC voltage is phase shifted with respect to the first and second AC voltages.

7. The circuit of claim 1, wherein:
the first high-pass filter is configured to receive a first AC voltage at the first AC input referenced to a ground terminal;
the second high-pass filter is configured to receive a second AC voltage at the second AC input referenced to the ground terminal; and
the amplifier has a supply voltage input referenced to the ground terminal.

8. The circuit of claim 1, further comprising:
a first resistor coupled between the first output and the amplifier input; and
a second resistor coupled between the second output and the amplifier input.

9. A system, comprising:
a conductive chassis having a first ground terminal, the conductive chassis adapted to be coupled to a switching circuit having a second ground terminal and having a first switching frequency, the second ground terminal electrically isolated from the first ground terminal;
an active electromagnetic interference (EMI) filter having an output and first and second inputs, the active EMI filter configured to:
receive a first AC voltage having a second switching frequency at the first input referenced to the first ground terminal;
receive a second AC voltage having the second switching frequency at the second input referenced to the first ground terminal, in which the second AC voltage is phase shifted with respect to the first AC voltage;
sense noise having the first switching frequency on at least one of the first or second inputs; and
generate an injection signal at the output based on the detected noise;
in which the output is coupled to at least one of the first or second inputs.

10. The system of claim 9, wherein the first switching frequency is greater than the second switching frequency.

11. The system of claim 9, wherein a polarity of the injection signal is opposite a polarity of the detected noise.

12. The system of claim 9, wherein the active EMI filter includes an inverting amplifier configured to generate the injection signal.

13. The system of claim 12, wherein the inverting amplifier has a supply voltage input referenced to the first ground terminal.

14. The system of claim 9, wherein the active EMI filter includes a high-pass filter.

15. The system of claim 9, wherein the active EMI filter includes: a first high-pass filter configured to receive the first AC voltage; and a second high-pass filter configured to receive the second AC voltage.

16. The system of claim 9, wherein the output is coupled to only one of the first or second inputs.

17. A system, comprising:
a passive electromagnetic interference (EMI) filter having first and second terminals; and
an active EMI filter having a ground terminal, an output and first and second alternating current (AC) inputs, the first and second AC inputs referenced to the ground terminal and respectively coupled to the first and second terminals, in which the active EMI filter is configured to generate an injection signal at the output based on noise at the first and second AC inputs, a polarity of the injection signal is opposite a polarity of the noise, and the output is coupled to at least one of the first and second AC inputs.

18. The system of claim 17, wherein the active EMI filter includes:
a high-pass filter circuit having a filter output and the first and second AC inputs; and
an inverting amplifier having an amplifier input and an amplifier output, the amplifier input coupled to the filter output, and the amplifier output coupled to at least one of the first or second AC inputs.

19. The system of claim 17, wherein the active EMI filter includes:
an amplifier having an amplifier input and an amplifier output;
a first high-pass filter coupled between the first AC input and the amplifier input; and
a second high-pass filter coupled between the second AC input and the amplifier input.

20. The system of claim 19, further comprising a capacitor coupled between the amplifier output and at least one of the first or second AC inputs.
